(19) United States
(12) Patent Application Publication
(10) Pub. No.: US 2009/0015147 A1
(43) Pub. Date: Jan. 15, 2009

(54) DISPLAY ELEMENT WITH PARTITION STRUCTURES IN DISPLAY AREAS AND FABRICATION METHOD THEREOF

(75) Inventors: Fu-Kang Chen, Taichung County (TW); Jhih-Ping Lu, Yi-Lan City (TW); Chao-Feng Sung, Miaoli County (TW); Yuh-Zheng Lee, Hsinchu City (TW); Chao-Kai Cheng, Miaoli County (TW)

Correspondence Address: QUINTERO LAW OFFICE, PC, 2210 MAIN STREET, SUITE 200, SANTA MONICA, CA, 90405, US

(73) Assignee: INDUSTRIAL TECHNOLOGY RESEARCH INSTITUTE, Hsinchu (TW)

(21) Appl. No.: 12/114,594

(22) Filed: May 2, 2008

(30) Foreign Application Priority Data
Jul. 11, 2007 (TW) TW96125188

(51) Int. Cl. H01J 1/62; H01J 9/00

(52) U.S. Cl. 313/504; 313/483; 445/1

(57) ABSTRACT

A display element with partition structures in display areas and a fabrication method thereof. The partition structure is formed on a display area of a display substrate by a solution process using the coffee ring effect. A display area of the display element is defined using the coffee ring ridge of the coffee ring as a partition structure. A covering material is inkjet printed or dispensed in the display area.

### BACKGROUND OF THE INVENTION

1. Field of the Invention

The invention relates to a display element with partition structures, and more particularly to a display element with partition structures in display areas formed by a solution process using the coffee ring effect.

2. Description of the Related Art

A conventional method for fabricating a liquid crystal display color filter is performed by three photolithography processes disposing three primary colors of color photoresist in pixel areas. The color photoresist is formed by spin coating such that more than 90% of the color photoresist is wasted. Specifically, the photolithography process requires using a lot of solvent such that the conventional method is not environmentally friendly and wastes a lot of material. Meanwhile, large-sized displays can not be satisfactorily fabricated using the conventional photolithography process.

U.S. Pat. No. 6,162,510 discloses a digital inkjet printing method. In this method, three primary color pigments of a color filter are inkjet printed in three cavities defined by a photolithography process to form a color filter. Although the inkjet printing method reduces color photoresist loss and is used for fabrication of large-sized displays, the photolithography process is still required to form partition structures for storing ink. Therefore, the method still wastes material and still has constraints with fabrication of large-sized displays.

The partition structures of a displays for storing ink require a width of less than about 20 μm; the narrower the width, the higher the color filter aperture ratio. However, current inkjet printing technology can only lower drop volume to 2 μl, wherein 1 pl is equal to 10⁻¹² liter. Note that 1 pl drop volume can be converted into a sphere with a diameter of more than about 12 μm. Accordingly, partition structures formed by inkjet printing technology have a width of about several tens to several hundreds of micrometers, which is not suitable for high resolution display partition structures.

In the conventional fabrication method for a polymer light emitting device (PLED), an ink storing cavity is formed by a photolithography process to define a cavity pattern on a conductive transparent substrate. Then, a light emitting material is coated in the defined cavity, performed several processes and packaged to complete the light emitting device. Although each layer of the PLED can be formed by inkjet printing technology to complete the light emitting device, the fabrication of the partition structures thereof still require a photolithography process.

U.S. Pat. No. 6,838,361 discloses a TFT fabrication method using a coffee ring effect. In this method, one material is disposed on a substrate to form a coffee ring. A coffee ring ridge of the coffee ring is used as a separating layer and a central part of the coffee ring film is removed by etching. Then, another material is disposed on the coffee ring ridge or two sides of coffee ring as a source/drain layer. After the source/drain electrodes are formed, the coffee ring is removed by a lift-off process. The disadvantage of this method includes an additional cost for the lift-off process. Additionally, the lift-off process damages the surfaces of the source/drain electrodes.

Therefore, a display element partition structure that does not require a photolithography process, can meet high resolution display requirements, does not waste a lot of material and does not have constraints with fabrication of large-sized displays is desirable.

### BRIEF SUMMARY OF THE INVENTION

The invention provides a display element, comprising a display substrate having a display area. At least a partition structure is disposed on the display area of the display substrate, wherein the partition structure defines at least a pixel area and the partition structure is a coffee ring ridge of a coffee ring formed from drying a solution. A covering material is disposed in the pixel area.

The invention further provides a method for fabricating a display element, comprising providing a display substrate having a display area. A material solution for partitioning is dispensed on the display area of the display substrate by a solution process and the material solution for partitioning is dried to form one or more than one coffer ring, wherein a coffee ring ridge of the coffee ring is a partition structure defining at least a pixel area. A covering material is inkjet printed or coated thereon to fill the pixel area.

A detailed description is given in the following embodiments with reference to the accompanying drawings.

### BRIEF DESCRIPTION OF THE DRAWINGS

The invention can be more fully understood by reading the subsequent detailed description and examples with reference to the accompanying drawings, wherein:

FIGS. 1A-1C show schematic cross sections of a mechanism for forming coffee rings;

FIGS. 2A-2G show schematic cross sections of processes for forming a circular partition structure according to a first embodiment of the invention;

FIG. 3 shows a schematic plane view of a circular partition structure array according to the first embodiment of the invention;

FIG. 4 shows an optical microscope photograph of a circular partition structure array according to the first embodiment of the invention;

FIGS. 5A-5D show schematic plane views of processes for forming a strip-shaped circular partition structure according to a second embodiment of the invention;

FIG. 6 shows a schematic plane view of a strip-shaped circular partition structure array according to the second embodiment of the invention;

FIG. 7 shows an optical microscope photograph of a strip-shaped circular partition structure array according to the second embodiment of the invention;

FIG. 8 shows a schematic plane view of a long strip-shaped circular partition structure array according to a third embodiment of the invention;

FIG. 9 shows an optical microscope photograph of a long strip-shaped circular partition structure array according to the third embodiment of the invention;

FIG. 10 shows an optical microscope photograph of a color filter formed by inkjet printing three primary colors of photoresist on the long strip-shaped circular partition structure array according to the third embodiment of the invention;

FIGS. 11A-11D show schematic cross sections of processes for controlling a distance between coffee ring ridges of the partition structures according to one embodiment of the invention; and

FIGS. 12A-12C show the measured results of the partition structures by a white-light interferometer, wherein the partition structures are formed according to the fabrication method for FIGS. 11A-11D, and the distances of moving the inkjet printer head are 100 μm, 130 μm and 150 μm, respectively.

### DETAILED DESCRIPTION OF THE INVENTION

The following description is of the best-contemplated mode of carrying out the invention. The description is provided for illustrating the general principles of the invention and is not meant to be limiting. The scope of the invention is best determined by reference to the appended claims.

The invention utilizes a solution process combined with a coffee ring effect to form a coffee ring ridge. The invention substitutes the conventional partition structure is formed by the photolithography process with the coffee ring ridge. The partition structure of the invention, using only inkjet printing, can be used in a display element to achieve fabrication of large-sized displays, a high resolution display, and low material waste.

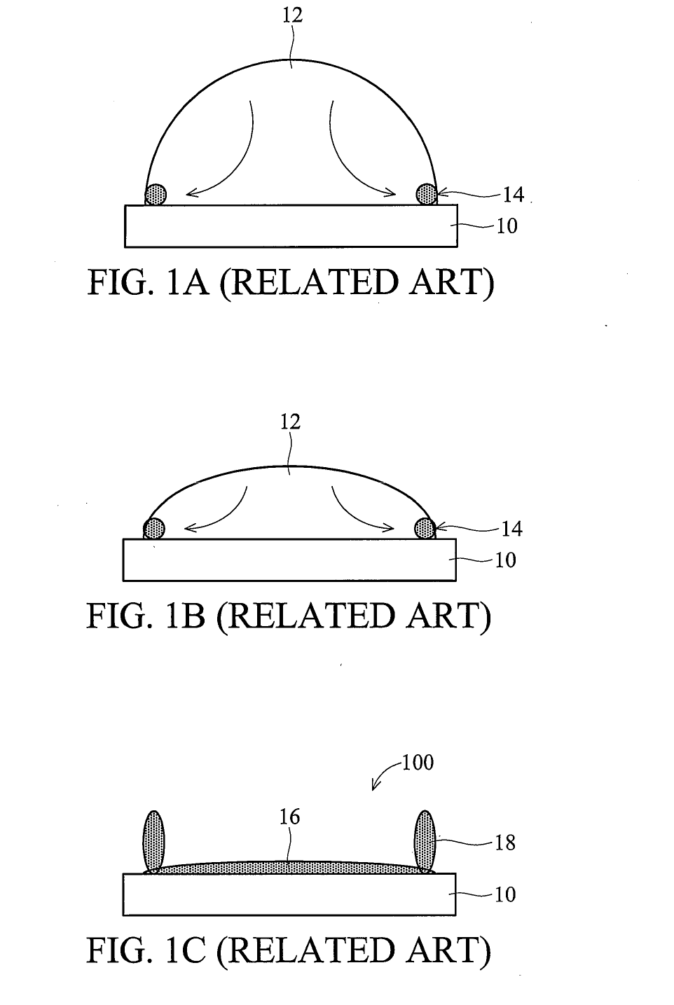

A mechanism for forming coffee rings is shown in FIGS. 1A to 1C. The mechanism can be referenced in Nature, Vol. 389, 1997, Robert D. Deegan, Olgica Bakajin et al., “Capillary Flow as the Cause of Ring Stains from Dried Liquid Drops”. In this article, the natural phenomenon of a solution containing a solid solute drying into a coffee ring is illustrated. An ink drop 12 is formed on a substrate 10, and then a perimeter of the drop is rapidly dried to form a contact line 14. Note that the characteristic pattern of the coffee ring is a form of capillary flow in which pinning of the contact line of the drying drop ensures that liquid evaporating from the edge is replenished by liquid from the interior. The phenomenon is due to a geometrical constraint: the free surface, constrained by a pinned contact line, squeezes the fluid outward to compensate for evaporative losses. Finally, a coffee ring 100 is formed which has a thin central part 16 and two thick and narrow ridges 18.

The invention utilizes a micro-drop formed by a solution process and the natural phenomenon of a solution drop drying into a coffee ring to make a micro-line structure of the coffee ring ridge. The coffee ring ridge can be used as a micro-receiver structure for storing an inkjet printing ink and as a partition structure of display elements.

The invention utilizes a material solution for partitioning, to be disposed on a display area of a display substrate by a solution process and then dried into a coffee ring. The coffee ring ridge can be used as a partition structure to define at least a pixel area. The pixel area defined by the partition structure can be a central part of the coffee ring or an area between two adjacent coffee ring ridges. The material solution for partitioning, which is used in the solution process, may be a solution formed from a soluble organic or inorganic material such as polymethyl methacrylate (PMMA), polyvinyl alcohol (PVA) or photoacrylate dissolved in a solvent. The solvent may be a watery liquid or an oily liquid such as xylene. The solution process can be a patterned solution process including contact printing, inkjet printing or dispensing.

In the embodiments of the invention, various shapes of the partition structures such as a circular, ellipse, strip, long strip-shaped circular or polygon partition structure can be formed by different inkjet printing methods. The circular partition structure can be formed by using an inkjet printer head to inkjet print one or more than one drop of material solution for partitioning at a fixed location. The long strip-shaped circular partition structure can be formed by using an inkjet printer head moving continuously along a direction to inkjet print a plurality of drops of the material solution for partitioning.

The circular partition structure can define a pixel area of a display. The long strip-shaped circular partition structure has a long side parallel to one edge of a display element and shorter than the length of the display element edge. The long strip-shaped circular partition structure can define a plurality of pixel areas of a display. After one partition structure is formed on a substrate by an inkjet printer head, the inkjet printer head can move by a constant distance to inkjet print another partition structure on the substrate until the display area of the substrate is filled with the partition structures. For example, a plurality of the circular partition structures can form an array arrangement. A long strip-shaped circular partition structure can form a horizontal or vertical arrangement.

The described partition structures are formed from the coffee ring ridges of the coffee rings and have a ridge-shaped structure. Meanwhile, a central part of the coffee ring is in the partition structure and has a thickness lower than that of the coffee ring ridge. The central part of the coffee ring is a thin layer structure. In one embodiment of the invention, the central part of the coffee ring can be retained in the partition structure and then a covering material is inkjet printed or coated on the central part of the coffee ring in the partition structure to form a display element with partition structures. In another embodiment of the invention, before inkjet printing or coating the covering materials, the central part of the coffee ring can be removed by a surface micro-etching method.

The covering material may be one or more than one kind of material, such as three primary colors of red, green and blue of photoresists of a color filter, light emitting materials of an organic light emitting diode or liquid crystal materials. For example, the three primary colors of photoresists can be inkjet printed or coated in sequence in the partition structures to form a color filter. The materials of an organic light emitting device such as a light emitting conjugated organic molecular material or a blend of more than two light emitting materials, for example, the derivatives of polyfluorene (PF), poly(N-vinylcarbazole) (PVK) or poly(phenylene vinylene) (PPV) can be inkjet printed or coated in the partition structures to form an organic light emitting device. In addition, the liquid crystal materials with different colors such as twisted-nematic, cholesteric, smectic, discotic or lyotropic liquid crystal materials can be inkjet printed or coated in the partition structures to form a liquid crystal display such as an electronic book. One skilled in the art should appreciate that the other covering materials can be used to form other displays or display elements.

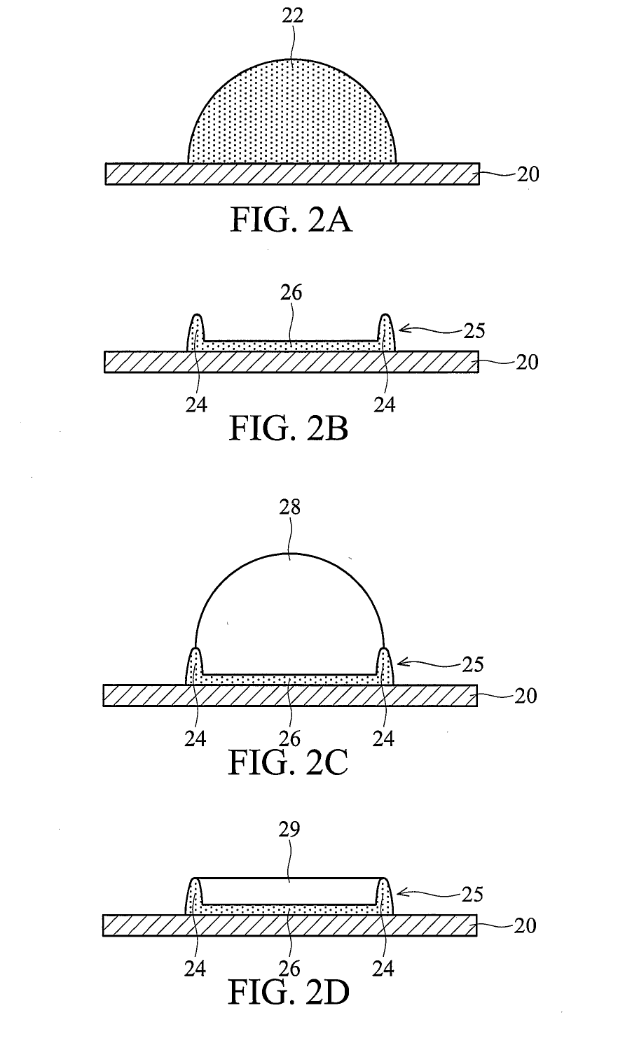

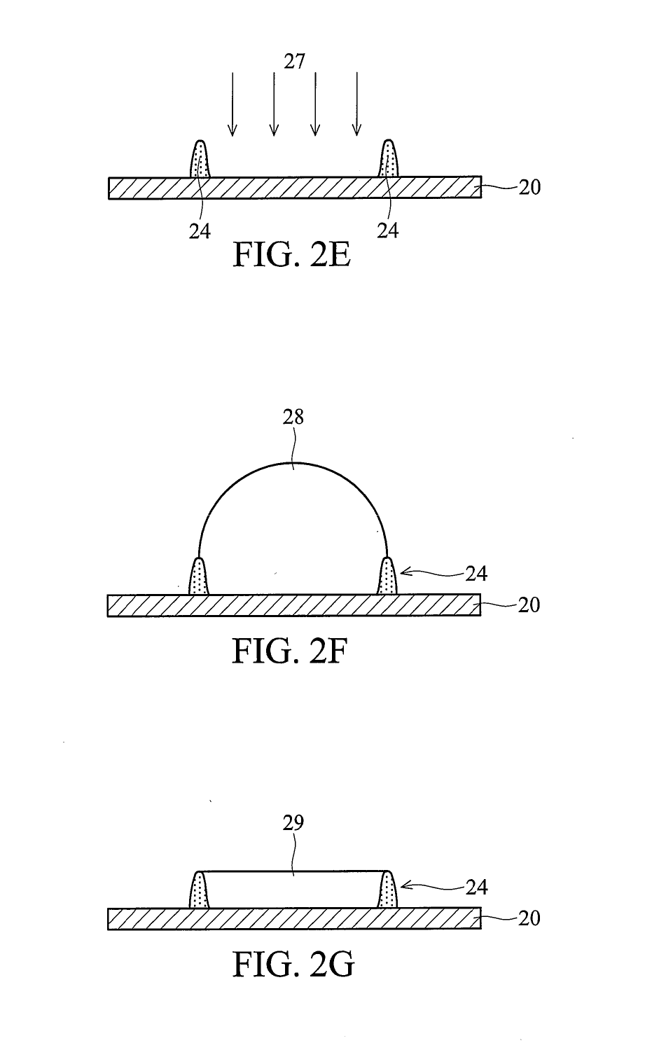

A first embodiment of the invention is a display element having a circular partition structure, the cross sections of the fabrication processes are shown in FIGS. 2A to 2D. Referring to FIG. 2A, a display substrate 20 such as a color filter substrate, an organic light emitting device substrate or a liquid crystal display substrate is provided. The material of the substrate may be glass, plastic or metal. An inkjet printer head is used to inkjet print a material solution for partitioning 22 on a display area of the display substrate 20 to form a dot. The material solution for partitioning 22 is such as polymethyl methacrylate (PMMA) dissolved in a solvent of xylene. The inkjet printer head can inkjet print one or more than one drop of material solution for partitioning at a fixed position to form a circular partition structure. The number of inkjet printing drops can determine the diameter of the circular partition structure; more inkjet printing drops, equals to a larger circular partition structure diameter.

Referring to FIG. 2B, the drop of the material solution for partitioning 22 is dried into a circular coffee ring thin film 25, which has a thin central part 26 and a thick, narrow coffee ring ridge 24 to form a circular micro-receiver structure 25 having a higher periphery. The coffee ring ridge 24 is the circular partition structure of the invention. The coffee ring ridge 24 has a width of about 1˜50 μm and a height of about 0.01˜10 μm.

Next, referring to FIG. 2C, another material solution 28, different from the material solution for partitioning, such as an organic light emitting diode material, for example, a light emitting conjugated organic molecular material or a blend of more than two light emitting materials, is disposed on the organic light emitting device substrate 20 having the micro-receiver structure 25 by a dispensing device. The organic light emitting diode material may be PF, PVK, PPV or the derivatives thereof. In one embodiment of the invention, a color photoresist can be inkjet printed on a color filter substrate 20 having the micro-receiver structure 25. In another embodiment of the invention, a liquid crystal material can be inkjet printed on a liquid crystal display substrate 20 having the micro-receiver structure 25. The coffee ring ridge of the micro-receiver structure 25 can be a partition structure, such that the solution 28 is limited in the structure of the micro-receiver structure 25. Next, referring to FIG. 2D, the solution 28 is dried into a thin film 29 to form a pixel area of an organic light emitting device, a color filter or a liquid crystal display having the circular partition structure. One skilled in the art should appreciate that the organic light emitting device or the liquid crystal display further comprises other components such as an electrode layer, of which, will not be described.

Moreover, referring to FIG. 2E, in another embodiment of the invention, after the coffee ring thin film 25 of FIG. 2B is formed, the central part 26 of the coffee ring thin film 25 can be removed by a surface micro-etching method 27, leaving a coffee ring ridge 24 as the partition structure. The surface micro-etching method may be performed by a plasma, immersion, spraying, dispensing, or printing surface micro-etching method or combinations thereof. The spraying, dispensing or printing surface micro-etching method is practiced by sprinkling a solvent on the substrate to etch the thin central part of the coffee ring.

Then, referring to FIGS. 2F to 2G, another material solution 28 is inkjet printed in the partition structure 24, wherein the solution 28 directly contacts with the substrate 20 and is dried into the thin film 29.

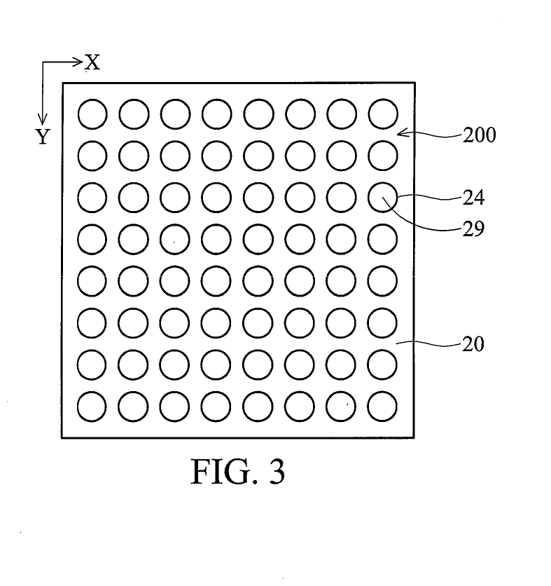

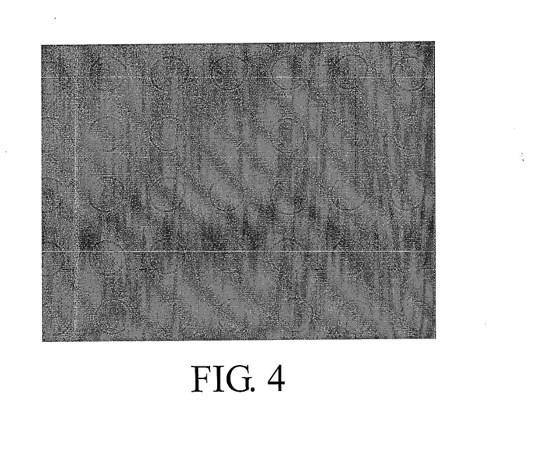

Referring to FIG. 3, the inkjet print head is moved by a constant distance along an X-direction and a Y-direction on the substrate 20, repeating the above described steps to form the circular partition structures until the substrate is filled with the circular partition structures to form an array 200 of the circular partition structures. As shown in FIG. 4, a photograph of the array 200 of the circular partition structures is taken by an optical microscopy. The circular partition structure has a total diameter of about 150 μm, and the distance between the circular partition structures along the X-direction and a Y-direction is about 300 μm. The coffee ring ridge of the circular partition structure has a width of about 20 μm and a height of about 1 μm.

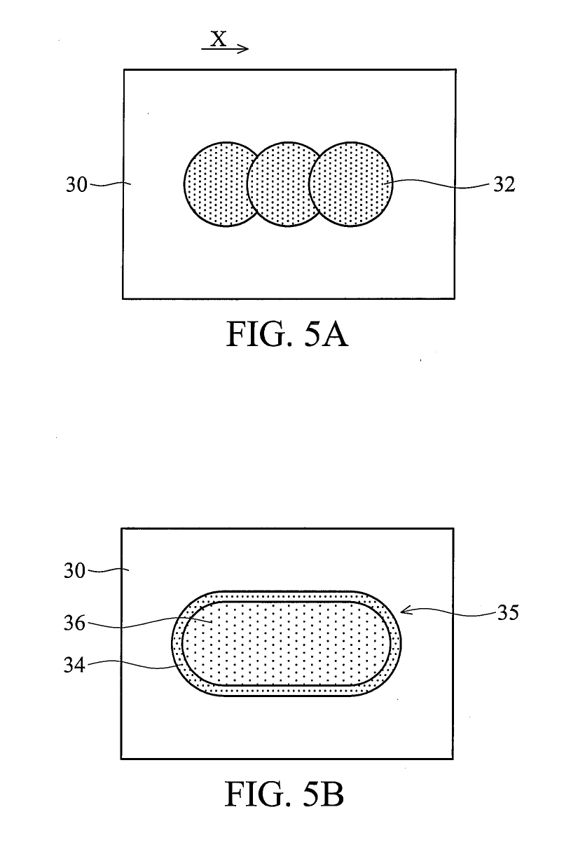

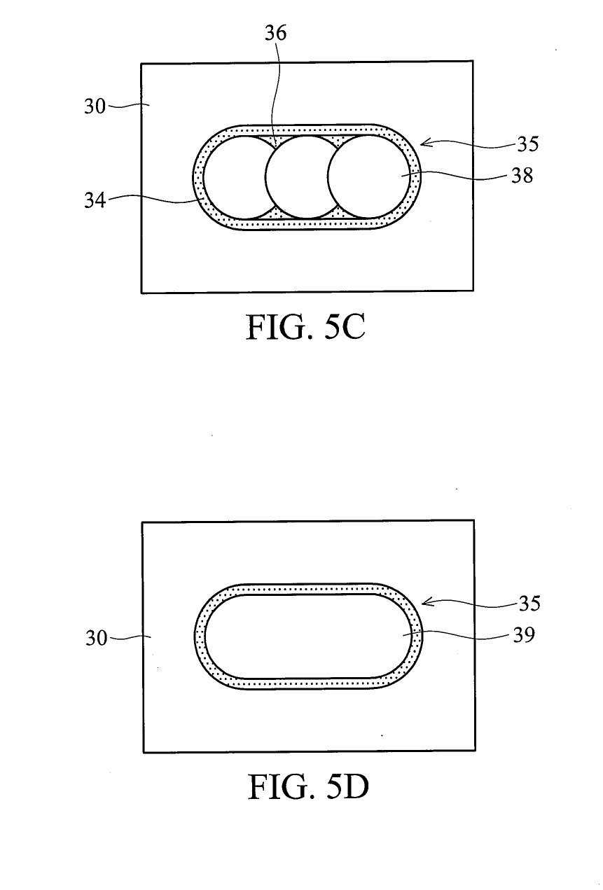

In a second embodiment of the invention, a display device having a strip-shaped circular partition structure is provided. The plan views of the fabrication process are shown in FIGS. 5A to 5D. A plurality of drops of a material solution for partitioning 32 are inkjet printed on a substrate 30 by continuously moving an inkjet printer head along an X-direction, wherein the drops are overlapped. Then, the drops are dried to form a strip-shaped circular coffee ring film 35. The strip-shaped circular coffee ring film 35 has a thin central part 36 and a high, narrow coffee ring ridge 34 to form a strip-shaped circular micro-receiver structure 35 having a higher periphery. The coffee ring ridge of the coffee ring film 35 is a strip-shaped circular partition structure. Next, a covering material solution 38 is inkjet printed in the strip-shaped circular micro-receiver structure 35 and is dried into a thin film 39 to complete a pixel area structure of a display element.

In another embodiment of the invention, after the strip-shaped circular coffee ring film 35 of FIG. 5B is formed, the central part 36 of the coffee ring film 35 can be removed by the surface micro-etching method 27, leaving the coffee ring ridge 34 as a strip-shaped circular partition structure. Then, a covering material solution 38 is inkjet printed in the strip-shaped circular partition structure 34 to contact with the substrate 30 and then dried into a thin film 39.

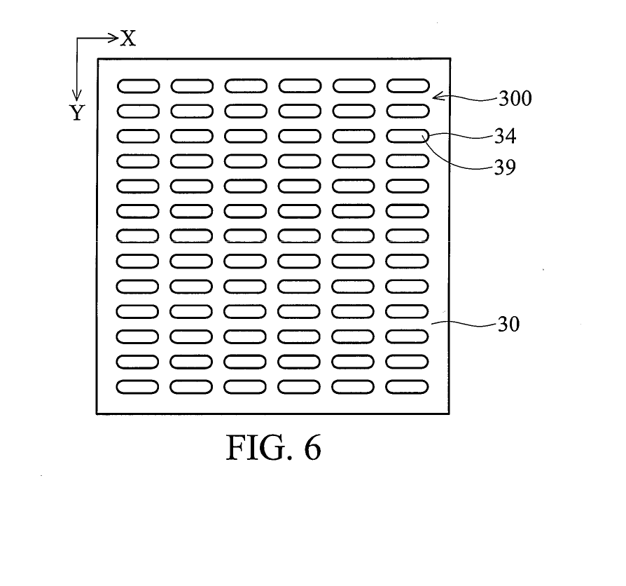

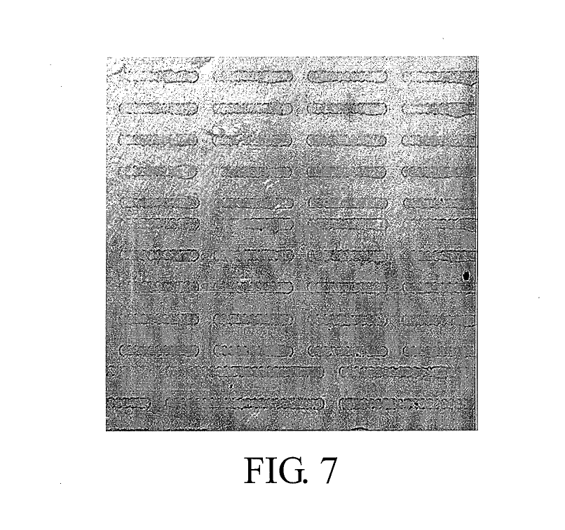

Referring to FIG. 6, the inkjet print head is moved by a constant distance along an X-direction and a Y-direction on the substrate 30 to repeat the above described process of forming the strip-shaped circular partition structure until the substrate is filled with the strip-shaped circular partition structures to form an array 300 of the strip-shaped circular partition structures. As shown in FIG. 7, a photograph of the array 300 of the strip-shaped circular partition structures is taken by an optical microscopy. The strip-shaped circular partition structure has a total length of about 1050±4.4 μm and a total width of about 92±3.9 μm. The distance between the strip-shaped circular partition structures along the X-direction and a Y-direction is about 300 μm. The coffee ring ridge of the strip-shaped circular partition structure has a width of about 20 μm and a height of about 1 μm.

The above description is an embodiment of forming a strip-shaped circular partition structure with a long side parallel to an X-axis. In another embodiment of the invention, the continuous inkjet printing direction of the inkjet printer head can be changed to a Y-direction, such that a strip-shaped circular partition structure with a long side parallel to a Y-axis can be formed.

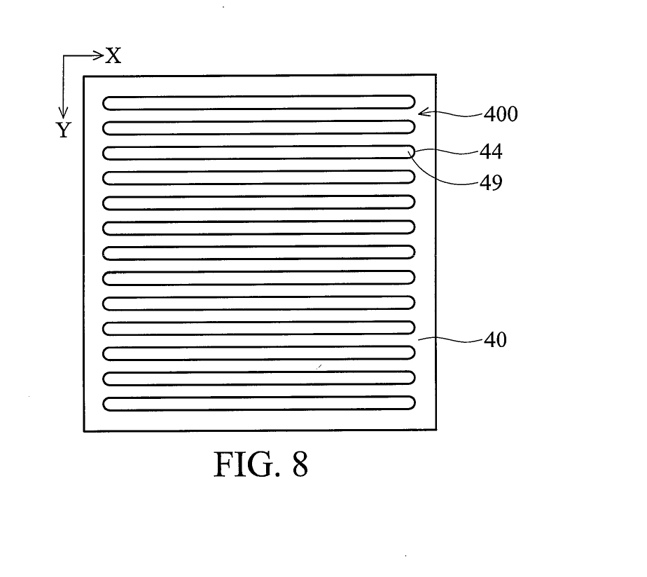

In a third embodiment of the invention, a display element having a long strip-shaped circular partition structure is provided. Referring to FIG. 8, the fabrication process of the third embodiment is similar to that of the second embodiment. A plurality of drops of a material solution for partitioning is inkjet printed on a substrate 40 by continuously moving the inkjet printer head along an X-direction until a long strip-shaped structure has a length substantially equal to a length of the substrate edge. Then, the long strip-shaped structure is dried into a long strip-shaped circular coffee ring film. The long strip-shaped circular coffee ring film has a thin central part and a high, narrow coffee ring ridge to form a long strip-shaped circular micro-receiver structure having a higher periphery. The coffee ring ridge of the coffee ring film is a long strip-shaped circular partition structure of the invention. Then, the inkjet printer head is moved by a constant distance along the Y direction on the substrate 40, repeating the above described process until the substrate is filled with the long strip-shaped circular partition structures to form an array 400 of the long strip-shaped circular partition structures. Then, a covering material solution is inkjet printed in the long strip-shaped circular partition structure 44 and then dried into a thin film 49. In another embodiment of the invention, the central part of the coffee ring film can be removed by the surface micro-etching method, leaving the coffee ring ridge as a long strip-shaped circular partition structure.

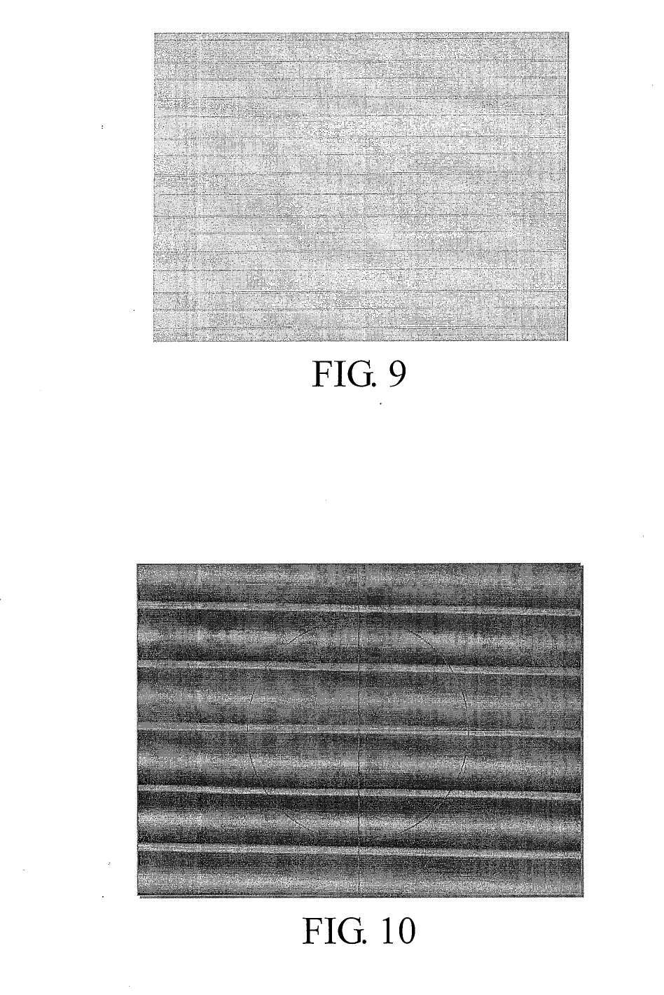

As shown in FIG. 9, a photograph of the array 400 of the long strip-shaped circular partition structures taken by an optical microscopy, the long strip-shaped circular partition structure has a length of about 60000 μm and a width of about 130 μm. The distance between the long strip-shaped circular partition structures in the Y-direction is about 130 μm. The coffee ring ridge of the long strip-shaped circular partition structure has a width of about 20 μm and a height of about 1 μm. Next, three colors of red, green and blue of color photoresist solution are inkjet printed respectively between the long strip-shaped circular partition structures in sequence and then dried to form a color filter with the long strip-shaped circular partition structures as shown in FIG. 10.

The above description is the embodiment of forming a long strip-shaped circular partition structure with a long side parallel to an X-axis. In another embodiment of the invention, the continuous inkjet printing direction of the inkjet printer head can be changed to a Y-direction, such that a long strip-shaped circular partition structure with a long side parallel to a Y-axis can be formed.

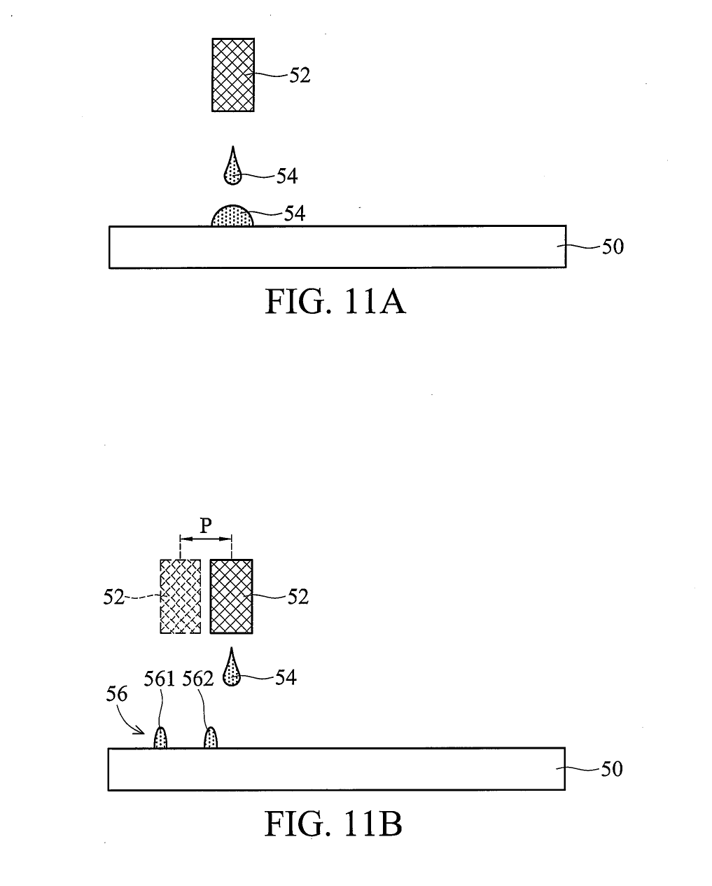

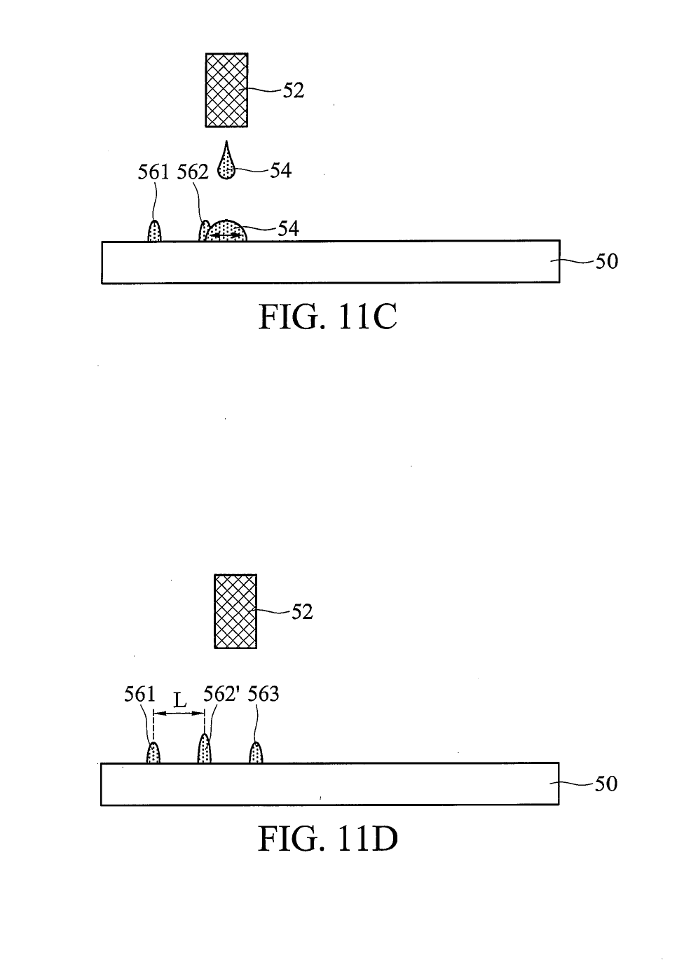

The invention further provides a method for controlling a distance between the coffee ring ridges of the partition structures. The cross sections of the fabrication process are shown in FIGS. 11A to 11D. An inkjet printer head 52 is moved along a first direction parallel to one edge of a substrate 50, for example, an X-direction, to continuously inkjet print a plurality of drops 54, and then the drops 54 are dried into a first long strip-shaped circular partition structure 56. Then, referring to FIG. 11B, the inkjet printer head returns to the original printing position of the first partition structure and then moves by a distance P along a second direction perpendicular to the first direction, for example, a Y-direction, to continuously inkjet print a plurality of drops 54 on the substrate. Note that, the distance P is not larger than a width from a coffee ring ridge 561 to a coffee ring ridge 562 of the partition structure 56. Then, as shown in FIG. 11C, the coffee ring ridge 562 of the first long strip-shaped circular partition structure 56 is affected by the solvent of the drop 54 and is squeezed toward the orientation of the coffee ring ridge 561. Then, as shown in FIG. 11D, one coffee ring ridge of the second long strip-shaped circular partition structure is combined with one coffee ring ridge of the first long strip-shaped circular partition structure to form a coffee ring ridge 562′, wherein the distance L between the coffee ring ridge 562′ and the coffee ring ridge 561 is approximate or equal to the distance P for moving the inkjet printer head. The above described steps are repeated until the substrate is filled with the long strip-shaped circular partition structures. The long strip-shaped circular partition structures formed by the above described method have the distance L between the coffee ring ridges approximate or equal to the distance P for moving the inkjet printer head along the second direction. Therefore, the distance between the coffee ring ridges of the long strip-shaped circular partition structures can be controlled by adjusting the distance of moving the inkjet printer head. Moreover, each distance between the coffee ring ridges of the long strip-shaped circular partition structures in the above described method is a constant distance.

In addition, the above described method can be used to control the distance between the circular partition structures or the strip-shaped circular partition structures. Referring to FIGS. 11A to 11D again, one or more than one drop 54 is inkjet printed on the substrate 50 by the inkjet printer head 52 and then dried into a first circular or strip-shaped circular partition structure 56. Next, as shown in FIG. 11B, the inkjet printer head is moved by a distance P along a first direction, for example, X-direction, to inkjet print another drops 54 on the substrate. Note that the distance P is not larger than a width from a coffee ring ridge 561 to a coffee ring ridge 562 of the partition structure 56. Then, as shown in FIG. 11C, the coffee ring ridge 562 of the first circular or strip-shaped circular partition structure 56 is affected by the solvent of the drop 54 and squeezed toward the orientation of the coffee ring ridge 561. Then, as shown in FIG. 11D, one coffee ring ridge of the second circular or strip-shaped circular partition structure is combined with one coffee ring ridge of the first circular or strip-shaped circular partition structure to form a coffee ring ridge 562′, wherein the distance L between the coffee ring ridge 562′ and the coffee ring ridge 561 is approximate or equal to the distance P of moving the inkjet printer head along the first direction. The above described steps are repeated until the first direction of the substrate is filled with the circular or strip-shaped circular partition structures. Next, a plurality of circular or strip-shaped circular partition structures are formed on the substrate along a second direction, for example, Y-direction, by the same method as previously described until the substrate is filled with the circular or strip-shaped circular partition structures. The circular or strip-shaped circular partition structures can be formed to fill the first direction of the substrate completely or not, and then be formed in the second direction of the substrate. The circular or strip-shaped circular partition structures formed by the above described method have the distance L between the coffee ring ridges in the first direction of the substrate approximate or equal to the distance P of moving the inkjet printer head along the first direction. Moreover, the circular or strip-shaped circular partition structures formed by the above described method have the distance between the coffee ring ridges in the second direction of the substrate approximate or equal to the distance of moving the inkjet printer head along the second direction. Therefore, the distance between the coffee ring ridges of the circular or strip-shaped circular partition structures can be controlled by adjusting the distance of moving the inkjet printer head. Moreover, for the above described method, each distance between the coffee ring ridges of the circular or strip-shaped circular partition structures along the same direction can be a constant distance.

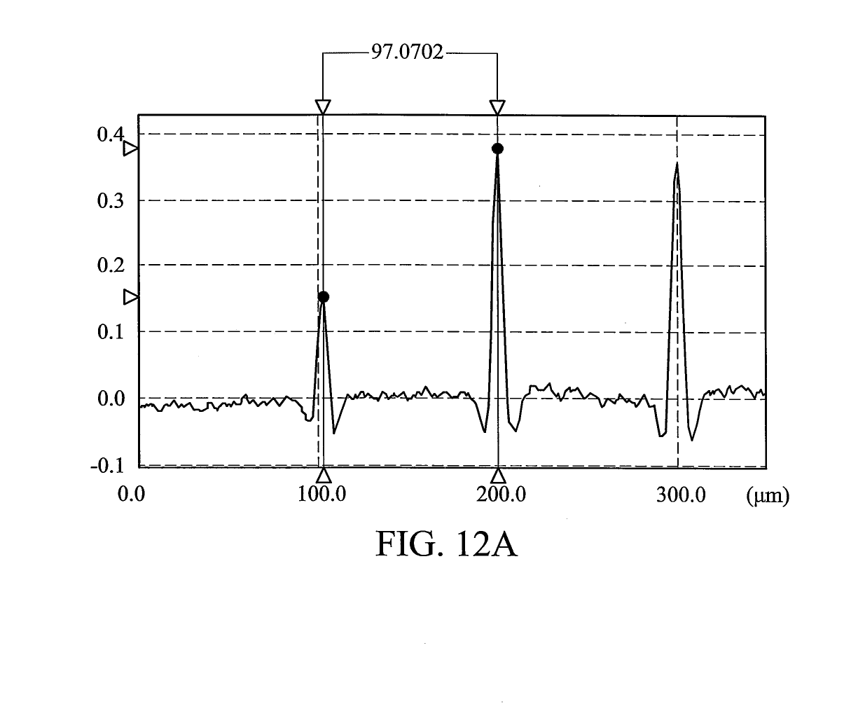

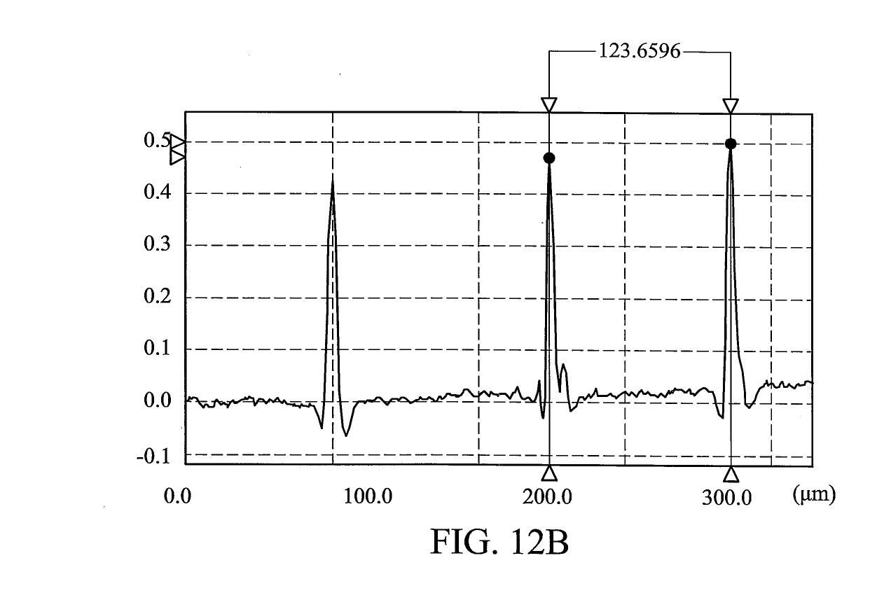

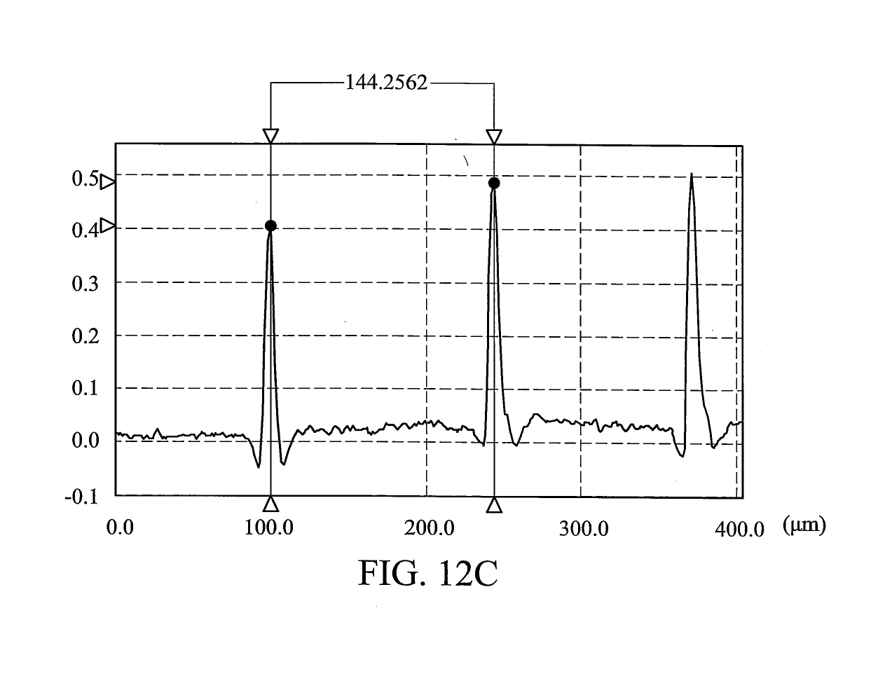

Referring to FIGS. 12A to 12C, the measuring results of the partition structures formed according to the above described method taken by a white-light interferometer are shown, wherein the distances of moving the inkjet printer head are 100 μm, 130 μm and 150 μm respectively. As shown in FIGS. 12A to 12C, the distances between the coffee ring ridges are respectively about 97.07 μm, 123.66 μm and 144.26 μm, while the distances of moving the inkjet printer head are respectively 100 μm, 130 μm and 150 μm. The distance between the coffee ring ridges can be controlled and is substantially equal to the distances of moving the inkjet printer head by the method for the invention.

According to the invention, a photolithography process is not required to form a micro-receiver structure having a higher periphery by inkjet printing in combination with the coffee ring effect. A micro-line structure of the coffee ring ridge can be used as the partition structure of the display element to achieve fabrication of large-sized displays, a high resolution display, and low material waste. Using inkjet printing without a photolithography process, the partition structure formed by the printing method for the invention has the advantages when compared to the conventional method such as having a more simplified fabrication process, lower material waste and lower cost.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A display element, comprising:
a display substrate, having a display area;
at least a partition structure disposed on the display area of the display substrate, wherein the partition structure defines at least a pixel area and the partition structure is a coffee ring ridge of a coffee ring formed from drying a solution; and
a covering material disposed in the pixel area.

2. The display element as claimed in claim 1, wherein the solution comprises a soluble organic material or a soluble inorganic material.

3. The display element as claimed in claim 1, wherein the pixel area defined by the partition structure is a central part of the coffee ring.

4. The display element as claimed in claim 1, wherein the pixel area defined by the partition structure is an area between the two adjacent coffee rings.

5. The display element as claimed in claim 1, wherein the partition structure is a ridge-shaped partition structure.

6. The display element as claimed in claim 1, wherein the partition structure comprises a circular, ellipse, strip, long strip-shaped circular or polygon partition structure.

7. The display element as claimed in claim 1, wherein the covering material comprises one or more than one material.

8. The display element as claimed in claim 1, wherein the display element is a color filter.

9. The display element as claimed in claim 1, wherein the display element is an organic light emitting device.

10. The display element as claimed in claim 1, wherein the display element is a liquid crystal display.

11. A method for fabricating a display element, comprising:
providing a display substrate, having a display area;
dispensing a material solution for partitioning on the display area of the display substrate by a solution process and drying the material solution for partitioning to form one or more than one coffer ring, wherein a coffee ring ridge of the coffee ring is a partition structure and defines at least a pixel area; and
inkjet printing or coating a covering material in the pixel area.

12. The method as claimed in claim 11, wherein the solution process is a patterned solution process, comprising contact printing, inkjet printing or dispensing.

13. The method as claimed in claim 11, further comprising a step of etching to remove a central part of the coffee ring, before inkjet printing or coating the covering material.

14. The method as claimed in claim 11, wherein the material solution for partitioning comprises a soluble organic material or a soluble inorganic material.

15. The method as claimed in claim 11, wherein the covering material comprises one or more than one material.

16. The method as claimed in claim 11, wherein the display element is a color filter and the covering material is a color photoresist.

17. The method as claimed in claim 11, wherein the display element is an organic light emitting device and the covering material is a material of the organic light emitting device.

18. The method as claimed in claim 11, wherein the display element is a liquid crystal display and the covering material is a liquid crystal.

19. The method as claimed in claim 11, wherein the partition structure comprises a circular, ellipse, strip, long strip-shaped circular or polygon partition structure.

20. The method as claimed in claim 19, further comprising a step for controlling a distance between the partition structures, comprising:
using an inkjet printer head to inkjet print the material solution for partitioning on the display substrate along a first direction parallel to an edge of the display substrate and to form a first long strip-shaped circular partition structure; and
moving the inkjet printer head along a second direction perpendicular to the first direction by a distance, inkjet printing the material solution for partitioning on the display substrate along the first direction to form a second long strip-shaped circular partition structure, wherein a distance between the partition structures substantially approximates to the distance of moving the inkjet printer head along the second direction.

21. The method as claimed in claim 19, further comprising a step for controlling a distance between the circular or strip partition structures, comprising:
using an inkjet printer head to inkjet print the material solution for partitioning on the display substrate and to form a first circular or strip partition structure; and
moving the inkjet printer head along a first direction parallel to an edge of the display substrate by a first distance, inkjet printing the material solution for partitioning on the display substrate to form a second circular or strip partition structure, wherein a distance between the partition structures in the first direction substantially approximates to the first distance of moving the inkjet printer head along the first direction.

22. The method as claimed in claim 21, wherein the step for controlling a distance between the circular or strip partition structures further comprises:
moving the inkjet printer head along a second direction perpendicular to the first direction by a second distance, inkjet printing the material solution for partitioning on the display substrate to form a third circular or strip partition structure; and
moving the inkjet printer head along the first direction by the first distance, inkjet printing the material solution for partitioning on the display substrate to form a fourth circular or strip partition structure, wherein a distance between the partition structures in the second direction substantially approximates to the second distance of moving the inkjet printer head along the second direction.
